(19) United States
(12) Patent Application Publication
(10) Pub. No.: US 2011/0076932 A1
(43) Pub. Date: Mar. 31, 2011

(54) FAN MOUNTING SYSTEM

(75) Inventor: Zhan-Yang Li, Shenzhen City (CN)

(73) Assignees: HONG FU JIN PRECISION INDUSTRY (ShenZhen) Co., LTD, Shenzhen City (CN); HON HAI PRECISION INDUSTRY CO., LTD., Tu-Cheng (TW)

(21) Appl. No.: 12/715,646

(22) Filed: Mar. 2, 2010

(30) Foreign Application Priority Data
Sep. 29, 2009 (CN) 200910307948.0

(51) Int. Cl. H05K 5/02

(52) U.S. Cl. 454/184

(57) ABSTRACT

A fan mounting system includes a chassis, a support bracket attached to a panel of the chassis, and a fan installed in the chassis. The support bracket defines a opening. The at least one opening includes an entrance portion and an engaging portion narrower than the entrance portion. The fan has a pair of latch members engaged with the opening. The latch members are capable of moving together with the fan from the entrance portion to the engaging portion along a first direction for securing the fan in the chassis, and moving from the engaging portion to the entrance portion along a second direction opposite to the first direction for detaching the fan from the supporting bracket.

### BACKGROUND

1. Technical Field

The present disclosure relates to fan mounting systems, and more particularly to a fan mounting system for conveniently mounting fans in a server.

2. Description of Related Art

Large server systems are generally systems including many servers, and demand for large servers systems has grown in recent years. One of the biggest issues in computer systems is heat dissipation. Because the server systems have to process a great number of tasks, their reliability is more critical than general computer systems. In order to maintain normal operation of the server systems, heat must be dissipated effectively. One of the approaches for dissipating heat is to increase the number of cooling fans.

Hot-plug fans are commonly used in server systems since it allows the fans to be replaced immediately after malfunctioning without having to shut down the server. Furthermore, hot-plug fans also have fastening structures for coupling with the servers. The most commonly adopted approach is fastening the hot-plug fan to the server with screws or bolts. However, the use of screws or bolts is comparatively inconvenient for making fast insertion or replacement of the hot-plug fan. Various screwless fastening structures are also adopted for facilitating easy mounting or removing of the fans. However, the fastening structure is usually disposed between adjacent fans in the server chassis and takes up much space, and this leaves less room for fans capable of being installed in the server system. Decreasing the number of fans installed in the server system will decrease a heat dissipation ability of the server system.

What is needed, therefore, is to provide a fan mounting system that allows fast and convenient installation or removal of the fans and does not take up much space.

### BRIEF DESCRIPTION OF THE DRAWINGS

FIG. 1 is a disassembled view of a fan mounting system for mounting cooling fans in a server chassis in accordance with an embodiment.

FIG. 2 is an exploded view of one of the cooling fans in FIG. 1.

FIG. 3 is an assembled view of FIG. 2, but viewed from another direction.

FIG. 4 is an assembled view of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

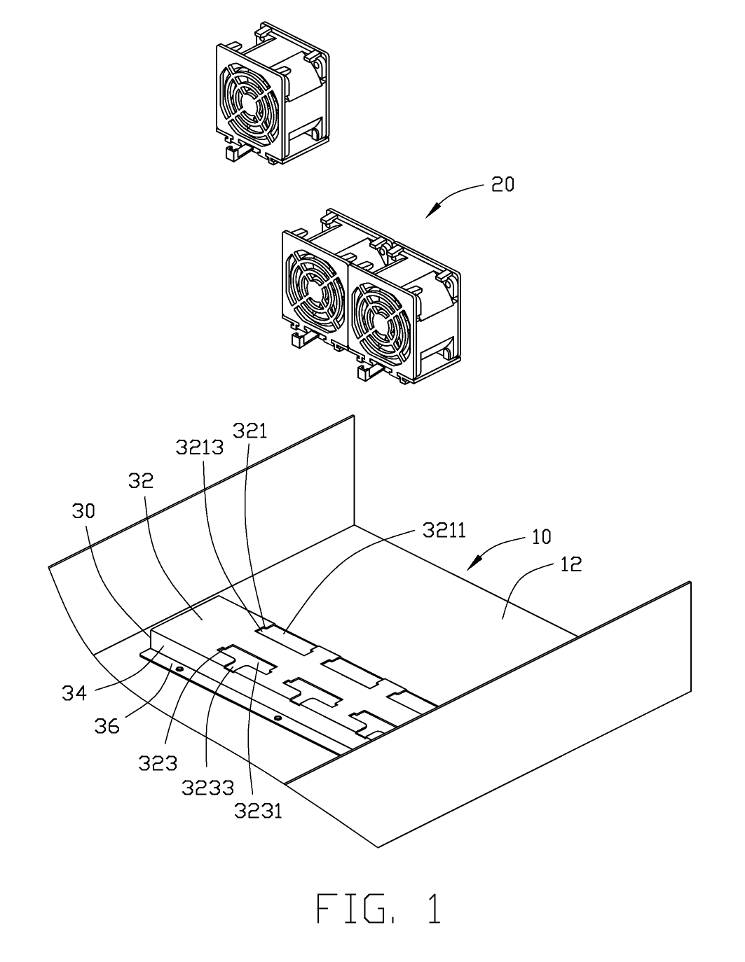

Referring to FIG. 1, an embodiment of a fan mounting system includes a server chassis 10 and a plurality of cooling fans 20. The server chassis 10 includes a bottom panel 12. A supporting bracket 30 is secured on the bottom panel 12 of the server chassis 10. The cooling fans 20 are configured to be mounted on the supporting bracket 30 in the server chassis 10.

A supporting bracket 30 includes a supporting panel 32 spaced away from and parallel to the bottom panel 12 of the server chassis 10, a pair of supporting flanges 34 extend downward from two opposite side edges of the supporting panel 32. Also, a pair of securing flanges 36 respectively extends from the supporting flanges 34 and are secured on the bottom panel 12 of the server chassis 10. Pairs of openings are defined in the supporting panel 32 for respectively mounting the cooling fans 20. Each pair of openings is comprised of a first opening 321 and a second opening 323. The first opening 321 includes a securing portion 3211 and an entrance portion 3212, which is wider than the securing portion 3211. The second opening 323 has a mounting portion 3231 and an extending portion 3233 connect with the mounting portion 3231. The mounting portion 3231 have the same shape as the first opening 321 and also includes a wide entrance portion and a narrow engaging portion. The extending portion 3233 is the narrowest portion in the second opening 323.

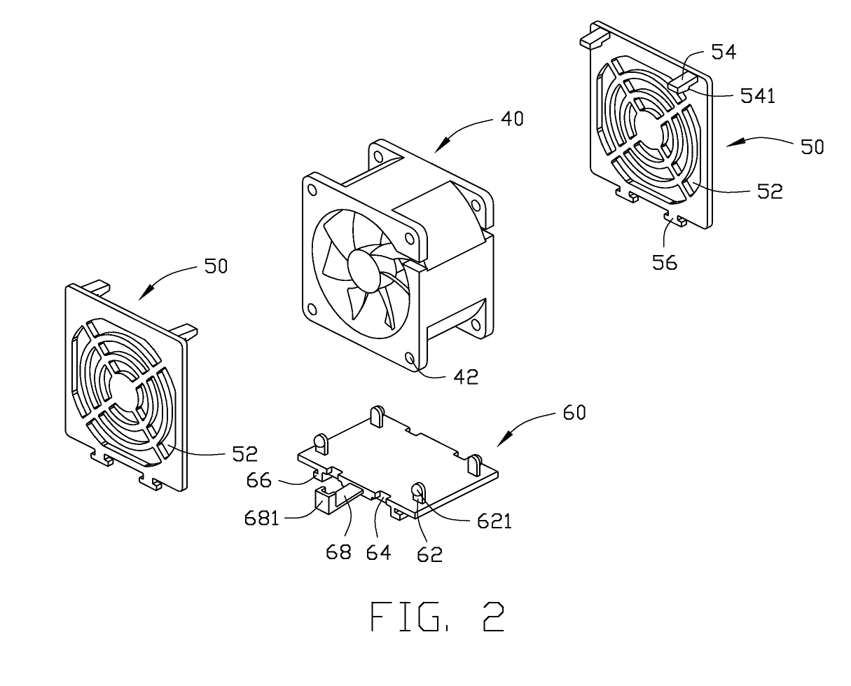

Referring to FIG. 2, each of the cooling fans 20 includes a main body 40, a pair of side panels 50 configured to be attached to opposite sides of the main body 40, and a base bracket 60 configured to be attached to a base of the main body 40. The main body 40 has a plurality of securing holes 42 defined in the lower and upper corners. Each of the side panels 50 has a plurality of air flow openings 52. A pair of resilient tabs 54 protrudes perpendicularly from an upper portion of each of the side panels 50. Wedge-shaped engaging protrusions 541 are located at a distal end of each of the resilient tabs 54. A pair of clasps 56 extend down from a bottom of each of the side panels 50. Four engaging tabs 62 protrude up from an upper surface of base bracket 60. A semi-circular protrusion 621 is located at an upper end of each of the engaging tabs 62 corresponding to the securing holes 42 of the main body 40. Two pairs of cutouts 64 are respectively defined at opposite side edges of the base panel 61 corresponding to the clasps 56 of the side panels 50. Two pairs of L-shaped latch members 66 extend downwardly from a bottom surface of the base bracket 60 and respectively adjacent to the two opposite side edges of the side panel 61. A resilient lever 68 extends from a front side of the base panel 61 of the base bracket 60. A handle portion 681 protrudes upwardly from a distal end of the lever 68. The resilient lever 68 has a slight incline downward relative to a horizontal axis in its original natural state.

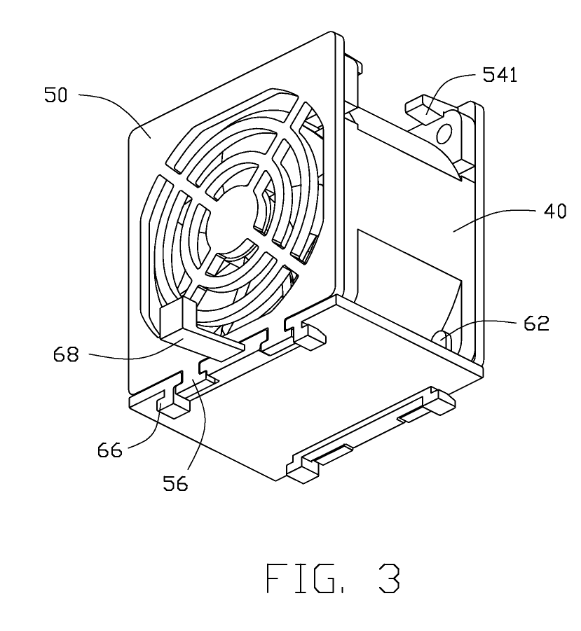

Referring to FIG. 3, in assembling the cooling fan 20, the side panels 50 are attached to opposite sides of the main body 40 respectively. Each of the resilient tabs 54 is deformed upwardly until the engaging protrusion 541 is engaged with an inner surface of one of the upper corners of the main body 40. The clasps 56 of the side panels 50 are engaged in the cutouts 64 of the base bracket 60. The engaging tabs 62 are pushed against inner surfaces of the lower corners of the main body 40, and the protrusions 621 of the engaging tabs 62 are engaged in the lower securing holes 42 of the main body 40.

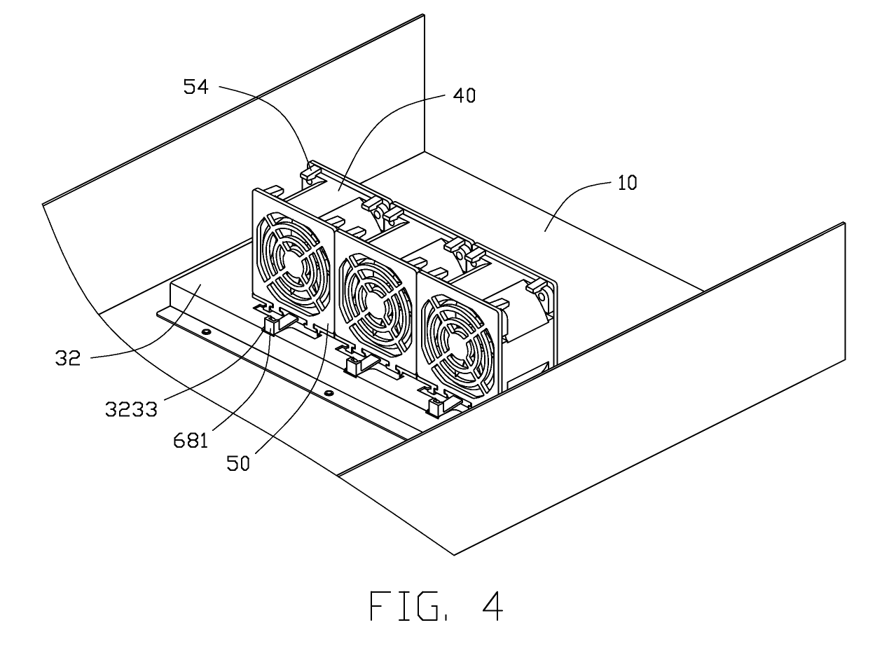

Referring to FIG. 4, the cooling fan 20 is installed in the server chassis 10. The two pairs of L-shaped latch members 66 of the cooling fan 20 are inserted into the first opening 321 and the second opening 323 via the wide entrance. Then the cooling fan 20 is moved rearward until the L-shaped latch members 66 are engaged with the narrow engaging portions of the first opening 321 and the second opening 323. The L-shaped latch members 66 are pushed against the rear edges of the first opening 321 and the second opening 323. The free end of the lever 68 is slightly sunken and engages the extending portion 3233 of the second opening 323. The cooling fan 20 is then securely attached on the supporting bracket 30 in the server chassis 10. In above described manner, other cooling fans 20 are capable of being attached in the server chassis 10 for improving the heat dissipation ability of the system.

In disassembly, the handle 681 of the lever 68 of the cooling fan 20 is pulled upward until the free end of the lever 68 is disengaged from the extending portion 3233 of the second opening 323. The cooling fan 20 is moved forward until the L-shaped latch members 66 are moved to the wide entrance portions of the first opening 321 and the second opening 323. Then the cooling fan 20 can be pulled up and detached from the server chassis 10.

In one embodiment, the fan mounting system allows fast and convenient installation or removal of the cooling fans 20. The cooling fans 20 are closely adjacent to each other without any gaps. Thus, the fan mounting system is comparatively space saving and will not cause a reduction of the number of fans capable of being installed in the server chassis 10.

While the present disclosure has been illustrated by the description of preferred embodiments thereof, and while the preferred embodiments have been described in considerable detail, it is not intended to restrict or in any way limit the scope of the appended claims to such details. Additional advantages and modifications within the spirit and scope of the present disclosure will readily appear to those skilled in the art. Therefore, the present disclosure is not limited to the specific details and illustrative examples shown and described.

What is claimed is:

1. A system comprising:
a chassis comprising of a panel;
a support bracket attached to the panel of the chassis, the support bracket defining at least one opening, and the at least one opening comprising an entrance portion and an engaging portion that is narrower than the entrance portion;
a fan configured to be installed in the chassis, the fan having a pair of latch members engaged with the at least one opening;
wherein the latch members are capable of moving, together with the fan, from the entrance portion to the engaging portion along a first direction for securing the fan in the chassis and from the engaging portion to the entrance portion along a second direction, opposite to the first direction, for detaching the fan from the supporting bracket.

2. The system of claim 1, wherein the fan comprises a resilient lever with a free end that resists against an edge of the at least one opening for preventing the fan moving along the second direction.

3. The system of claim 2, wherein the lever is slightly inclined downwardly relative to the second direction.

4. The system of claim 2, wherein the at least one opening further comprises a latch portion, and the free end of the lever is engaged with an edge of the latch portion for preventing the fan moving along the second direction.

5. The system of claim 4, wherein the latch portion is narrower than the engaging portion, and the engaging portion and the latch portion are connected with opposite sides of the entrance portion.

6. The system of claim 2, wherein the fan comprises a main body, a pair of side panels attached to opposite sides of the main body, and a base bracket attached to a base of the main body; and the latch members extend from a bottom surface of the base bracket.

7. The system of claim 6, wherein a plurality of securing holes are defined in corners of the main body, a plurality of engaging tabs extend from an upper surface of the base bracket, and each of the engaging tabs comprises a protrusion engaged in one of the securing holes.

8. The system of claim 7, wherein at least a clasp extends from a bottom of each of the side panels, and at least a cutout is defined in the base bracket for engaging with the clasp.

9. The system of claim 8, wherein the clasp is inverted T-shaped.

10. A system comprising:
a chassis comprising of a panel;
a support bracket attached to the panel of the chassis, the support bracket defining a plurality of openings, each of the openings comprising an entrance portion and an engaging portion that is narrower than the entrance portion;
a plurality of fans secured to the support bracket, each of the fans having a pair of latch members engageable with engaging portion and disengagable from the entrance portion.

11. The system of claim 10, wherein the support bracket includes a support panel parallel to the panel of the chassis, and the plurality of openings are defined in the support panel.

12. The system of claim 10, wherein each of the fans comprises a resilient lever with a free end that resists against an edge of one of the openings.

13. The system of claim 12, wherein a handle is located at the free end of the opening.

14. The system of claim 12, wherein each of the openings further comprises a latch portion, and the free end of the lever engages with an edge of the latch portion.

15. The system of claim 14, wherein the latch portion is narrower than the engaging portion, and the engaging portion and the latch portion respectively connect with opposite sides of the entrance portion.

16. The system of claim 10, wherein each of the fans comprises a main body, a pair of side panels attached to opposite sides of the main body, and a base bracket attached to a base of the main body; and the latch members extend from a bottom surface of the base bracket.

17. The system of claim 16, wherein the latch members are L-shaped and symmetrical to each other.

18. The system of claim 16, wherein a plurality of securing holes are defined in corners of the main body, a plurality of engaging tabs extend from an upper surface of the base bracket, and each of the engaging tabs comprises a protrusion engaged in one of the securing holes.

19. The system of claim 18, wherein at least a clasp extends from a bottom of each of the side panels, and at least a cutout is defined in the base bracket for engaging with the clasp.

20. The system of claim 19, wherein the clasp is inverted T-shaped.
